(19) United States
(12) Patent Application Publication
(10) Pub. No.: US 2019/0363172 A1
(43) Pub. Date: Nov. 28, 2019

(54) METHOD FOR MANUFACTURING ACTIVE MATRIX SUBSTRATE, METHOD FOR MANUFACTURING ORGANIC EL DISPLAY DEVICE, AND ACTIVE MATRIX SUBSTRATE

(71) Applicant: SHARP KABUSHIKI KAISHA, Sakai City, Osaka (JP)

(72) Inventors: Takao SAITOH, Sakai City (JP); Yohsuke KANZAKI, Sakai City (JP); Masahiko MIWA, Sakai City (JP); Masaki YAMANAKA, Sakai City (JP); Seiji KANEKO, Sakai City (JP)

(73) Assignee: Sharp Kabushiki Kaisha, Sakai City, Osaka (JP)

(21) Appl. No.: 16/064,538

(22) PCT Filed: Mar. 7, 2017
(86) PCT No.: PCT/JP2017/009010

§ 371 Date: Sep. 13, 2018

(51) Int. Cl. H01L 29/49; H01L 29/786; H01L 29/66; H01L 27/12

(52) U.S. Cl. CPC H01L 29/4908; H01L 27/1214; H01L 29/6675; H01L 29/78645

(57) ABSTRACT

In formation of a gate electrode, a second metal film is formed on a first metal film by adding oxygen or nitrogen in an inert gas atmosphere, the first metal film and the second metal film are patterned and subjected to a plasma treatment using oxygen or nitrogen, to form a third metal film. Thus, a gate electrode is formed. This prevents formation of needle-shaped or granular crystal while a reduction in production efficiency is suppressed.

### TECHNICAL FIELD

The disclosure relates to a method for manufacturing an active matrix substrate and a method for manufacturing an organic EL display device.

### BACKGROUND ART

In a Thin Film Transistor (TFT) using a low-temperature polysilicon, a so-called top gate structure, in which a gate electrode is disposed on a layer above a semiconductor layer, is adapted.

The gate electrode is formed by patterning, and impurity ions are then implanted into the semiconductor layer of the TFT, to form such a TFT. Subsequently, the semiconductor layer is annealed for activation of the semiconductor layer. At that time, a surface of the gate electrode is oxidized by heat since the gate electrode is exposed.

In PTL 1, the semiconductor layer is annealed in an environment where oxygen in the atmosphere is removed as much as possible during annealing for activation. According to PTL 1, oxidation of the surface of the gate electrode can be suppressed.

### CITATION LIST

### Patent Literature

PTL 1: JP 2015-64592 A

### SUMMARY

### Technical Problem

The gate electrode is also heated by annealing the semiconductor layer. Subsequently, the temperature in a furnace in which annealing is carried out is abruptly returned to the atmospheric temperature. In this case, the oxidized surface of the gate electrode is abruptly cooled. As a result, a needle-shaped or granular crystal is formed on the surface of the gate electrode. Due to the needle-shaped or granular crystal formed on the surface, the coverage of an insulating layer that covers the gate electrode may be deteriorated and the resistance value of the gate electrode may increase. This causes a decrease in yield.

In a method of PTL 1, it is necessary that the temperature in the furnace that is heated in a reduced pressure environment be slowly brought back to the atmospheric temperature after annealing. Therefore, the time required to complete the annealing is long. This causes a reduction in productivity.

In view of the above-described problems of the related art, an object of the disclosure is to prevent formation of a needle-shaped or granular crystal on a surface of a gate electrode due to heat generated during activation of a semiconductor layer in a TFT with a top gate structure while a reduction in productivity is suppressed.

### Solution to Problem

In order to solve the above-described problems, a method for manufacturing an active matrix substrate according to one aspect of the disclosure is a method for manufacturing an active matrix substrate including a Thin Film Transistor (TFT) with a top gate structure on a substrate including:

(i) forming a gate insulating film on the substrate, the gate insulating film covering a semiconductor layer formed in an island shape on the substrate; and

(ii) forming a gate electrode of the TFT on the gate insulating film,

wherein step (ii) includes (ii-a) forming a first metal film in an inert gas atmosphere, (ii-b) adding oxygen or nitrogen to the inert gas atmosphere to form a second metal film on the first metal film, and (ii-c) patterning the first and second metal films and subjecting the first and second metal films to a plasma treatment using oxygen or nitrogen.

In order to solve the above-described problems, an active matrix substrate according to one aspect of the disclosure is an active matrix substrate having a TFT with a top gate structure on a substrate including: a gate insulating film formed on the substrate, the gate insulating film covering a semiconductor layer formed in an island shape on the substrate; and a gate electrode of the TFT formed on the gate insulating film, wherein the gate electrode includes a first metal film including a metal material having the highest metal purity of the gate electrode, a second metal film layered on the first metal film, the second metal film being including a metal material obtained by oxidation or nitridation of the metal material, and a third metal film covering the first and second metal films, the third metal film being including the metal material obtained by oxidation or nitridation of the metal material.

### Advantageous Effects of Disclosure

One aspect of the disclosure has an effect of preventing formation of a needle-shaped or granular crystal on a surface of a gate electrode due to heat generated during activation of a semiconductor layer in a TFT with a top gate structure, while a reduction in productivity is suppressed.

### BRIEF DESCRIPTION OF DRAWINGS

FIG. 1 is a cross-sectional view illustrating a configuration of an organic EL display device according to a first embodiment of the disclosure.

FIG. 2 is a plan view illustrating a configuration of a TFT substrate according to the first embodiment of the disclosure.

FIGS. 3A to 3F are cross-sectional views illustrating a process for manufacturing the TFT substrate according to the first embodiment of the disclosure.

FIG. 4 is a view illustrating a cross section of a gate electrode of the TFT substrate according to the first embodiment of the disclosure.

FIGS. 5A and 5B are views illustrating a state of a gate electrode, when the substrate having the gate electrode is removed from a furnace immediately after annealing.

FIGS. 6A and 6B are views illustrating a state of a gate electrode, when the substrate having the gate electrode is removed from a furnace, after annealing and allowing the temperature in the furnace to decrease down to 50° C.

FIGS. 7A and 7B are views illustrating a state of a gate electrode, when the substrate having the gate electrode is removed from a furnace after annealing in a low-oxygen environment.

FIG. 8 is a view illustrating a cross section of a gate electrode of a TFT substrate according to a second embodiment of the disclosure.

FIG. 9 is a view illustrating a cross section of a gate electrode of a TFT substrate according to a third embodiment of the disclosure.

FIG. 10 is a view illustrating a cross section of a gate electrode of a TFT substrate according to a fourth embodiment of the disclosure.

FIG. 11 is a chart showing a process of manufacturing a TFT substrate according to a fifth embodiment of the disclosure.

FIG. 12 is a cross-sectional view illustrating a configuration of the TFT substrate according to the fifth embodiment of the disclosure.

FIG. 13 is a cross-sectional view illustrating a configuration of a display region of a TFT substrate according to a sixth embodiment of the disclosure.

FIG. 14 is a cross-sectional view illustrating a configuration of a frame region of the TFT substrate according to the sixth embodiment of the disclosure.

FIG. 15 is a chart showing a process for manufacturing the TFT substrate according to the sixth embodiment of the disclosure.

### DESCRIPTION OF EMBODIMENTS

### First Embodiment

### Schematic Configuration of Organic EL Display Device 1

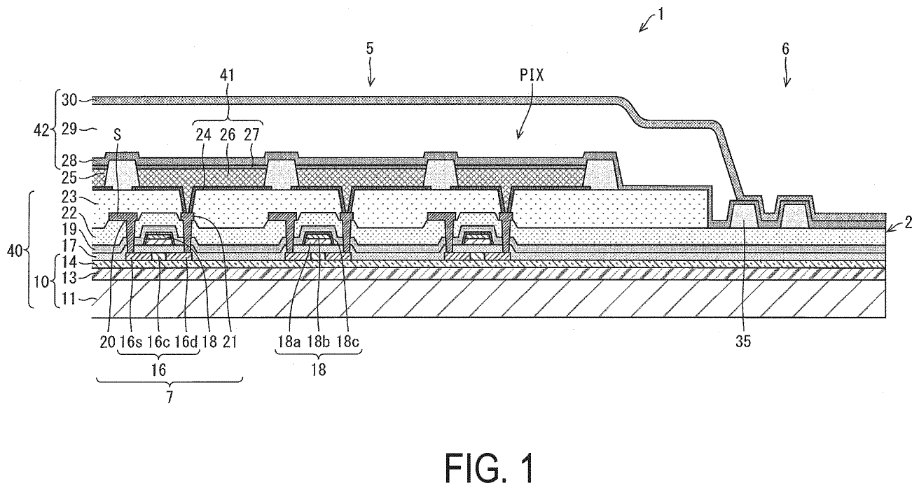

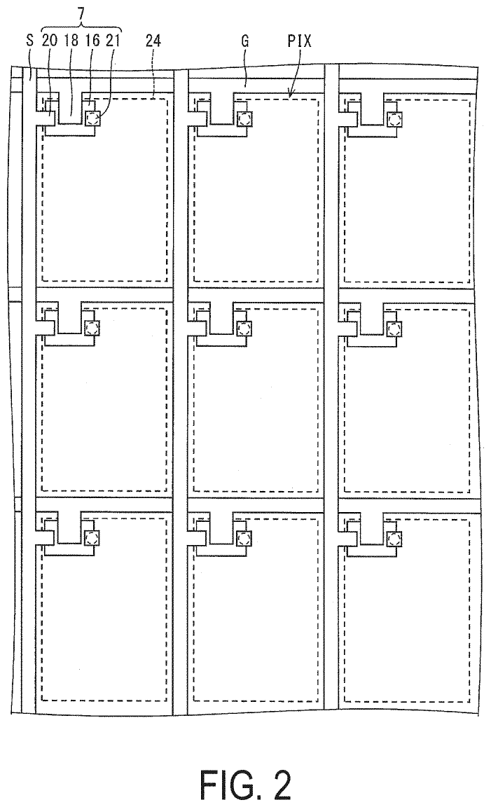

A schematic configuration of an organic EL display device 1 will be described by using FIGS. 1 and 2, as one example of a display device using a Thin Film Transistor (TFT) 7 according to an embodiment of the disclosure.

FIG. 1 is a cross-sectional view illustrating the configuration of the organic EL display device 1 according to a first embodiment of the disclosure. As illustrated in FIG. 1, the organic EL display device 1 includes an organic EL substrate 2 sealed with a thin film (Thin Film Encapsulation, TFE) and a drive circuit (not illustrated). The organic EL display device 1 may further include a touch panel.

The organic EL display device 1 has a display region 5 that has a pixel PIX disposed in a matrix and displays an image and a frame region 6 that is a peripheral region surrounding the display region 5 and does not have the pixel PIX.

The organic EL substrate 2 has a structure in which an organic EL element 41 and a sealing layer 42 are provided on a Thin Film Transistor (TFT) substrate 40 in this order from the side of the TFT substrate (active matrix substrate) 40.

The organic EL substrate 2 includes a support 11. The support 11 includes a transparent insulating material such as a plastic film and a glass substrate. On the entire surface of the support 11, a plastic film 13 including a resin such as a polyimide (PI), a moisture-proof layer 14, and the like are provided in this order from the side of the support 11.

On the moisture-proof layer 14, an island-shaped semiconductor layer 16, a gate insulating film 17 that covers the semiconductor layer 16 and the moisture-proof layer 14, a gate electrode 18 that is provided on the gate insulating film 17 and overlaps the semiconductor layer 16, a first interlayer film 19 that covers the gate electrode 18 and the gate insulating film 17, a second interlayer film 22 that covers the first interlayer film 19, and an interlayer insulating film 23 that covers the second interlayer film 22 are provided.

The semiconductor layer 16 has a channel region 16c, a source region 16s, and a drain region 16d. The gate electrode 18 is formed to cover the channel region 16c and a part of the source region 16s and a part of the drain region 16d.

A source electrode 20 is connected to the source region 16s and a drain electrode 21 is connected to the drain region 16d, via contact holes provided in the gate insulating film 17, the first interlayer film 19, and the second interlayer film 22.

A TFT 7 includes the semiconductor layer 16, the gate electrode 18, the source electrode 20, and the drain electrode 21. The TFT 7 is a switching element that is formed in each pixel PIX and controls drive of each of the pixels PIXs. The TFT 7 has a top gate structure (staggered type), in which the gate electrode 18 is formed as an upper layer on the semiconductor layer 16. In this embodiment, the semiconductor layer 16 includes a low-temperature polysilicon (LTPS).

The gate electrode 18 can include molybdenum, a molybdenum alloy containing molybdenum such as molybdenum tungsten (MoW), tungsten, a tungsten alloy such as tungsten tantalum, or the like.

In particular, it is preferable that the gate electrode 18 include molybdenum or a molybdenum alloy, rather than from tungsten or a tungsten alloy. This is because the resistance value is lower. However, when the gate electrode 18 includes molybdenum or a molybdenum alloy, a surface thereof is more easily oxidized by heat than that including tungsten or a tungsten alloy.

The surface is oxidized by heat, and the temperature is abruptly brought back to the atmospheric temperature, to cool the surface. In this case, a needle-shaped crystal (see FIG. 5) or a granular crystal (see FIG. 6) is formed on the surface of the gate electrode. When the needle-shaped or granular crystal is formed on the surface, the coverage of the first interlayer film 19 covering the gate electrode 18 may be deteriorated. This causes a decrease in yield. Due to the formation of needle-shaped or granular crystal, the resistance value of the gate electrode may increase. This also causes a decrease in yield. Therefore, when the gate electrode 18 includes molybdenum or a molybdenum alloy, it is particularly preferable that a procedure of preventing oxidation of the surface be carried out.

The gate electrode 18 has a first metal film 18a, a second metal film 18b layered on the first metal film 18a, and a third metal film 18c covering the first metal film 18a and the second metal film 18b. The details of the gate electrode 18 will be described below.

The support 11, the plastic film 13, and the moisture-proof layer 14, which are layers below the TFT 7, may be simply referred to as a substrate 10. That is, it may be also expressed that the TFT 7 is formed on the substrate 10.

The first interlayer film 19 and the second interlayer film 22 are inorganic insulating films including silicon nitride or silicon oxide. The second interlayer film 22 covers a leading wiring line (not illustrated), and the like. The interlayer insulating film 23 is an organic insulating film including a photosensitive resin such as an acrylic or a polyimide. The interlayer insulating film 23 covers the TFT 7 and a wiring line (not illustrated). Thus, unevenness on the TFT 7 and the wiring line (not illustrated) is leveled.

In this embodiment, the interlayer insulating film 23 is provided on the display region 5, but is not provided on the frame region 6. However, the interlayer insulating film 23 may be provided not only on the display region 5 but also on the frame region 6.

FIG. 2 is a plan view illustrating a configuration of the TFT substrate according to the first embodiment of the disclosure. As illustrated in FIG. 2, the gate electrode 18 of the TFT 7 is connected to a gate wiring line G and the source electrode 20 is connected to a source wiring line S. As seen from a direction perpendicular to a substrate surface of the organic EL substrate 2, a plurality of the gate wiring lines G arranged in parallel and a plurality of the source wiring lines S arranged in parallel intersect orthogonally. A region defined by the gate wiring line G and the source wiring line S is the pixel PIX.

The TFT 7 is provided in the pixel PIX and in the vicinity of an intersection between the gate wiring line G and the source wiring line S. A lower electrode 24 is formed in an island shape in the pixel PIX.

As illustrated in FIG. 1, the lower electrode 24 is formed on the interlayer insulating film 23. The lower electrode 24 is connected to the drain electrode 21 via a contact hole provided in the interlayer insulating film 23.

An organic EL element 41 includes the lower electrode 24, an organic EL layer 26, and an upper electrode 27. The organic EL element 41 is a light-emitting element capable of emitting light at high luminance by low-voltage direct current drive. The lower electrode 24, the organic EL layer 26, and the upper electrode 27 are layered in this order from the side of the TFT substrate 40. In this embodiment, layers between the lower electrode 24 and the upper electrode 27 are collectively referred to as the organic EL layer 26.

On the upper electrode 27, an optical adjustment layer that performs optical adjustment and an electrode protection layer that protects an electrode may be formed. In this embodiment, layers formed in each of the pixels PIXs including the organic EL layer 26, electrode layers (the lower electrode 24 and the upper electrode 27), and the optical adjustment layer and the electrode protection layer that are formed as necessary and are not illustrated in the drawings are collectively referred to as the organic EL element 41.

In the lower electrode 24, a hole is injected into (supplied to) the organic EL layer 26. In the upper electrode 27, an electrode is injected into the organic EL layer 26.

The hole and electron injected into the organic EL layer 26 are recombined in the organic EL layer 26, to form an exciton. When the formed exciton is decayed from an excited state to a ground state, light such as red light, green light, or blue light is emitted, and the emitted light exits from the organic EL element 41 to the outside.

An end of the lower electrode 24 having an island shape is covered with an edge cover 25. The edge cover 25 is formed on the interlayer insulating film 23 to cover the end of the lower electrode 24. The edge cover 25 is an organic insulating layer including a photosensitive resin such as an acrylic or a polyimide.

The edge cover 25 is disposed between the pixels PIXs adjacent to each other. The edge cover 25 prevents a short circuit of the upper electrode 27 that may be caused by concentration of the electrodes or a decrease in thickness of the organic EL layer 26 at the end of the lower electrode 24. Further, the concentration of electric field at the end of the lower electrode 24 is prevented by the presence of the edge cover 25. Thus, the deterioration of the organic EL layer 26 is prevented.

The organic EL layer 26 is provided at a region surrounded by the edge cover 25. In other words, the edge cover 25 surrounds an edge of the organic EL layer 26 and a side wall of the edge cover 25 is in contact with a side wall of the organic EL layer 26. When the organic EL layer 26 is formed by an inkjet method, the edge cover 25 functions as a bank that blocks a liquid material that forms the organic EL layer 26. The edge cover 25 has a tapered cross section.

The organic EL layer 26 is provided at the region surrounded by the edge cover 25 in the pixel PIX. The organic EL layer 26 can be formed by a vapor deposition method, an inkjet method, or the like.

For example, the organic EL layer 26 has a structure in which a hole injecting layer, a hole transport layer, a light-emitting layer, an electron transport layer, an electron injecting layer, and the like are layered in this order from the side of the lower electrode 24. One layer may have a plurality of functions. For example, instead of the hole injecting layer and the hole transport layer, a hole injection-cum-transport layer having functions of both the hole injecting layer and the hole transport layer may be provided. Instead of the electron injecting layer and the electron transport layer, an electron injection-cum-transport layer having functions of both the electron injecting layer and the electron transport layer may be provided. Between the layers, a carrier blocking layer may be appropriately provided.

The upper electrode 27 is formed in an island shape in each of the pixels PIXs by patterning. The upper electrodes 27 formed in the pixels PIXs are connected to each other through an auxiliary wiring line (not illustrated) or the like. The upper electrode 27 may not be formed in an island shape in each of the pixels and may be formed at the entire surface of the display region 5.

In this embodiment, the lower electrode 24 is described as an anode (pattern electrode or pixel electrode) and the upper electrode 27 is described as a cathode (common electrode). However, the lower electrode 24 may be a cathode and the upper electrode 27 may be an anode. In this case, the order of the layers constituting the organic EL layer 26 is inverted.

When the organic EL display device 1 is a bottom emission type that emits light from a back side of the support 11, a reflective electrode includes a reflective electrode material as the upper electrode 27 and a transparent or semi-transparent electrode includes a transparent or semi-transparent translucent electrode material as the lower electrode 24.

In contrast, when the organic EL display device 1 is a top emission type that emits light from the side of the sealing layer 42, the electrode structure is the reverse of that of the bottom emission type. That is, when the organic EL display device 1 is the top emission type, a reflective electrode is formed as the lower electrode 24 and a transparent or semi-transparent electrode is formed as the upper electrode 27.

A frame bank 35 (bank) is formed on the second interlayer film 22 within the frame region 6 to surround the display region 5 in a frame shape.

The frame bank 35 controls wetting and spreading of a liquid organic insulating material that forms an organic layer (resin layer) 29 of the sealing layer 42 during applying to the entire surface of the display region 5. When the organic insulating material is cured, the organic layer 29 is formed. The frame bank 35 has a tapered cross section.

In this embodiment, the frame bank 35 doubly surrounds the display region 5. However, the frame bank 35 may only singly surround the display region 5 or triply or greater surround the display region 5.

The frame bank 35 is an organic insulating film including a photosensitive resin such as an acrylic or a polyimide. For the frame bank 35, the same material as that for the edge cover 25 can be used. The frame bank 35 may be formed by patterning using photolithography or the like in the same step as that for the edge cover 25.

The frame bank 35 may include a material different from that for the edge cover 25 by patterning in a step different from that for the edge cover 25.

The sealing layer 42 includes an inorganic layer 28, the organic layer 29, and an inorganic layer 30 that are layered in this order from the side of the TFT substrate 40. The sealing layer 42 covers the organic EL element 41, the edge cover 25, the interlayer insulating film 23, the second interlayer film 22, and the frame bank 35. Between the upper electrode 27 and the sealing layer 42, an organic layer (resin layer) or an inorganic layer such as the optical adjustment layer and the electrode protection layer, which are not illustrated, may be formed, as described above.

The organic EL layer 26 is sealed with the sealing layer 42 (Thin Film Encapsulation, TFE). Thus, the sealing layer 42 prevents the deterioration of the organic EL element 41 due to moisture and oxygen permeated from the outside.

The inorganic layers 28 and 30 have a moisture-proof function that prevents permeation of moisture, and thus the deterioration of the organic EL element 41 due to moisture and oxygen is prevented.

The organic layer 29 may relax the stress of the inorganic layers 28 and 30 having a large film stress. Also, the organic layer 29 may level the surface of the organic EL element 41 by embedding a step, eliminate a pinhole, and suppress cracking during layering the inorganic layers, and film separation.

The aforementioned layered structure is one example. The sealing layer 42 is not limited to the aforementioned three-layer structure (the inorganic layer 28/the organic layer 29/the inorganic layer 30). The sealing layer 42 may have a structure in which an inorganic layer and an organic layer are layered in not less than four layers.

Examples of a material for the organic layer include organic insulating materials (resin materials) such as a polysiloxane, silicon oxide carbide (SiOC), an acrylate, a polyurea, parylene, a polyimide, and a polyamide.

Examples of a material for the inorganic layer include inorganic insulating materials such as silicon nitride, silicon oxide, silicon oxynitride, and Al₂O₃.

### Method for Manufacturing TFT Substrate 40

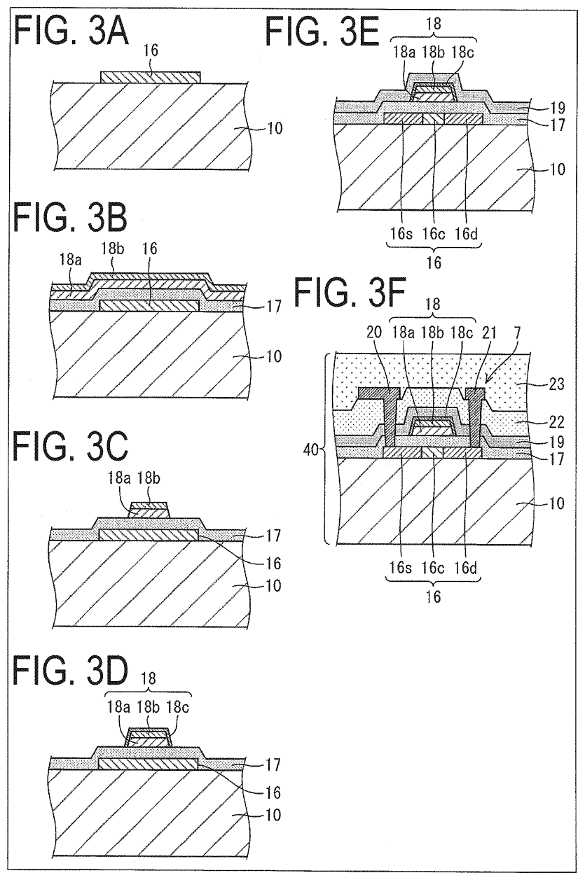

Next, one example of a method for manufacturing the TFT substrate 40 will be described by using FIGS. 1 and 3A to 3F.

FIGS. 3A to 3F are cross-sectional views illustrating a process for manufacturing the TFT substrate 40 according to the first embodiment of the disclosure. FIG. 3A is a view illustrating a state where the semiconductor layer 16 is formed on the substrate 10. FIG. 3B is a view illustrating a state where the gate electrode is formed. FIG. 3C is a view illustrating a state where a plasma treatment is carried out immediately after formation of the gate electrode. FIG. 3D is a view illustrating a state where the semiconductor layer 16 is activated. FIG. 3E is a view illustrating a state where the first interlayer film 19 is formed. FIG. 3F is a view illustrating a state where the interlayer insulating film 23 is formed.

When a polyimide (PI) or the like is applied to the support 11 as illustrated in FIG. 1, the plastic film 13 is formed on the support 11 (PI application step). On the plastic film 13, an inorganic insulating film including silicon nitride, silicon oxide, or the like is formed by CVD or the like. Thus, the moisture-proof layer 14 is formed on the plastic film 13 (moisture-proof layer forming step). As a result, the substrate 10 is manufactured.

As illustrated in FIG. 3A, the semiconductor layer 16 having an island shape is formed on the substrate 10.

In order to form the semiconductor layer 16 having an island shape, an amorphous silicon (a-Si) film is first formed on the substrate 10 by Chemical Vapor Deposition (CVD) or the like, and then irradiated with a laser beam, resulting in crystallization. Thus, a polysilicon (p-Si) film is formed. A resist film is formed on the polysilicon film and patterned by photolithography or the like. The polysilicon film is etched by using the patterned resist film as a patterning mask. Thus, the semiconductor layer 16 having an island shape is formed at a pixel forming region on the substrate 10.

As illustrated in FIG. 3B, the gate insulating film 17 including silicon nitride or silicone oxide is then formed on the substrate 10 to cover the semiconductor layer 16 by CVD or the like (gate insulating film forming step). Through the gate insulating film 17, impurities are doped (implanted) into the semiconductor layer 16.

Subsequently, the first metal film 18a and the second metal film 18b that form the gate electrode 18 are formed on the entire surface of the gate insulating film 17 (gate electrode forming step and metal film forming step). In this embodiment, the first metal film 18a and the second metal film 18b are formed by sputtering.

The metal material, that is a target, is placed in a furnace. In the furnace, the substrate 10 after completion of formation of the gate insulating film 17 is disposed to face the metal material. Herein, as the metal material, molybdenum or an alloy containing molybdenum is used.

Argon (Ar) as an inert gas is introduced into the closed furnace. A current is applied to an electrode in an inert gas atmosphere to initiate sputtering. As a result, the first metal film 18a is formed on the gate insulating film 17 (first step).

For example, the sputtering is carried out under conditions of from 0.2 to 0.5 Pa, from 3 to 10 W/cm², a flow rate of Ar of from 50 to 150 sccm, from 100 to 150° C., and from 100 to 300 nm.

After initiating the sputtering, an oxygen (O₂) gas or a nitrogen (N₂) gas is introduced into the furnace so that the upper layer with not less than 10 nm of the molybdenum or molybdenum alloy is converted into an oxide layer or a nitride layer.

The control of film thickness during the sputtering is carried out depending on the number of magnet movement regardless of time. For example, oxygen (O₂) or nitrogen (N₂) is introduced into the furnace during the last two to five magnet movements of all the magnet movements. A magnet is disposed on a back side of a target in the furnace, and has the same height as that of the target and a width of several tens centimeters. By a reciprocating motion of the magnet in the width direction, a metal film is deposited on the substrate.

Thus, the oxygen or nitrogen introduced into the furnace is added to the molybdenum or molybdenum alloy, to form the second metal film 18b on the first metal film 18a (second step).

Herein, oxygen is introduced into the furnace. As a result, molybdenum oxide or molybdenum alloy oxide as the second metal film 18b is formed on the first metal film 18a.

Therefore, the first metal film 18a and the second metal film 18b that form the gate electrode 18 are formed on the entire surface of the gate insulating film 17.

As illustrated in FIG. 3C, the first metal film 18a and the second metal film 18b are patterned by dry etching or wet etching (gate electrode patterning step).

Herein, it is preferable that the first metal film 18a and the second metal film 18b have a tapered shape (a shape in which a side surface is inclined so that the area is decreased from the bottom surface toward the top surface) because the coverage of the first interlayer film 19 over the gate electrode 18 is improved, where the first interlayer film 19 is formed to cover the gate electrode 18 in a subsequent step. For this reason, it is preferable that the first metal film 18a and the second metal film 18b be patterned by dry etching rather than wet etching. This is because the first metal film 18a and the second metal film 18b are easily formed in a tapered shape by dry etching.

The angle between the bottom surface and the side surface of the first metal film 18a and the second metal film 18b is referred to a taper angle. The taper angle is preferably not greater than 50°. When the first metal film 18a and the second metal film 18b are patterned by dry etching, the gate electrode having a taper angle of not greater than 50° can be formed by patterning. Thus, the coverage of the first interlayer film 19 for the gate electrode 18 can be sufficiently ensured.

It is difficult that the gate electrode 18 is formed to have a taper angle of not greater than 50° by wet-etching.

Therefore, the patterned first metal film 18a and second metal film 18b that form the gate electrode 18 are formed.

Herein, the side surfaces of the first metal film 18a and the second metal film 18b are exposed. Because the second metal film 18b includes oxidized molybdenum or oxidized molybdenum alloy, a needle-shaped or granular crystal is not likely to form on the surface even under heating followed by quenching. On the other hand, because the first metal film 18a includes molybdenum or a molybdenum alloy, a needle-shaped or granular crystal may form on the exposed side surface under heating followed by quenching.

As illustrated in FIG. 3D, the first metal film 18a and the second metal film 18b, which have the exposed side surfaces, are subjected to a plasma treatment using oxygen (O₂), nitrogen (N₂), or N₂O (plasma treatment step, third step).

The plasma treatment is carried out, for example, under conditions of from 0.2 to 1 W/cm², 50 to 300 Pa, a flow rate of N₂O of from 2000 to 5000 sccm, from 10 s to 60 s, and from 100 to 300° C.

Herein, the plasma treatment using nitrogen is carried out. Therefore, the third metal film 18c that covers the side surface of the first metal film 18a and the side surface and top surface of the second metal film 18b is formed.

As a result, the gate electrode 18 is formed on the gate insulating film 17 to overlap the semiconductor layer 16 via the gate insulating film 17.

The gate wiring line G (see FIG. 2) may include the same material as that for the gate electrode 18 and in the same step as that for the gate electrode 18, or include a material different from that for the gate electrode 18 and in a step different from that for the gate electrode 18.

Subsequently, impurity ions such as boron ions are injected into the semiconductor layer 16 by using the gate electrode 18 as a mask, as illustrated in FIG. 3E (ion injection step). As a result, the source region 16s and the drain region 16d between which the channel region 16c is interposed are formed in the semiconductor layer 16. The gate electrode 18 is exposed because the impurity ions are injected into the semiconductor layer 16 by using the gate electrode 18 as a mask.

In order to activate the semiconductor layer 16, the substrate is annealed by heating at from 350° C. to 450° C. in an atmospheric pressure (annealing step). Thus, a Si crystal defect, which is generated during injection of impurity ions into the semiconductor layer 16, is recrystallized and the semiconductor layer 16 is activated.

Herein, the gate electrode 18 is exposed. However, the surface is covered with third metal film 18c including molybdenum nitride or molybdenum alloy nitride in the gate electrode 18. Therefore, even when quenching is carried out by abruptly returning to the atmospheric temperature after annealing, a needle-shaped or granular crystal is not formed on the surface of the gate electrode 18.

This can prevent the occurrence of problems such as deterioration of coverage for the gate electrode and an increase in resistance value.

Further, the furnace, in which the substrate 10 is placed, may not be cooled to the atmospheric temperature from the temperature during annealing over a long period of time. Therefore, a reduction in production efficiency can be suppressed.

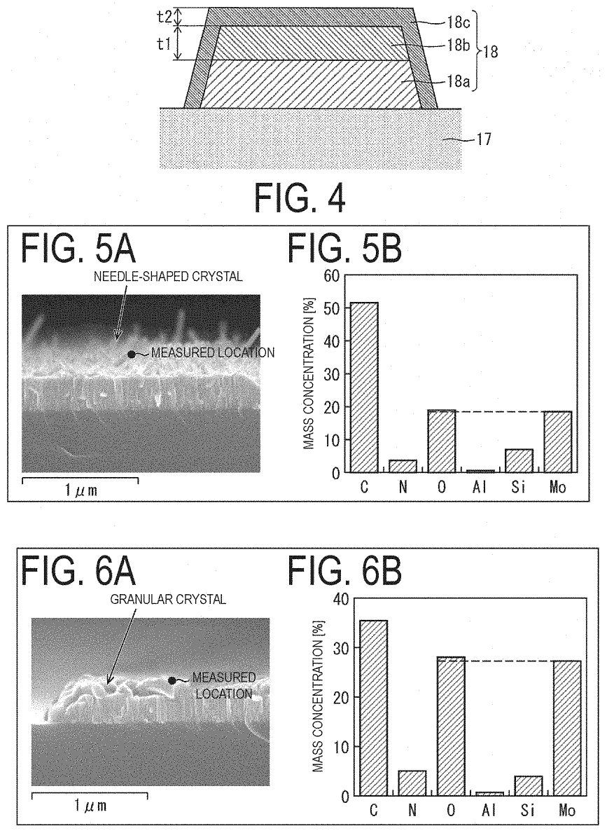

FIG. 4 is a view illustrating a cross section of the gate electrode. As illustrated in FIG. 4, the second metal film 18b is layered on the surface of the first metal film 18a. The second metal film 18b is formed by adding oxygen and forming a film from molybdenum or a molybdenum alloy by sputtering. Therefore, the thickness of the second metal film 18b is greater than that of the third metal film 18c formed by a plasma treatment using nitrogen or N₂O. Accordingly, the generation of needle-shaped and granular crystals on the surface of the first metal film 18a can be certainly prevented.

The thickness t1 of the second metal film 18b and the thickness t2 of the third metal film 18c satisfy the relationship t1>t2. For example, t1 is not less than 10 nm and t2 is not greater than 10 nm.

The third metal film 18c can be also formed on the side surfaces of the first metal film 18a and the second metal film 18b. Therefore, the first metal film 18a and the second metal film 18b can be completely covered without exposure.

As illustrated in FIG. 3E, the first interlayer film 19 including silicon nitride or silicon oxide is formed on the gate insulating film 17 to cover the exposed gate electrode 18 by CVD or the like under heating at about 250° C. (interlayer film forming step).

After the first interlayer film 19 is formed, the second interlayer film 22 including silicon nitride or silicon oxide is formed by CVD or the like, as illustrated in FIG. 3F. During the formation of the second interlayer film 22, the temperature applied to the substrate may be about 250° C.

Subsequently, contact holes are formed in the gate insulating film 17, the first interlayer film 19, and the second interlayer film 22, to expose a part of the source region 16s and a part of the drain region 16d of the semiconductor layer 16.

The source electrode 20 and the drain electrode 21 are formed by patterning using a publicly known technique. At that time, the source electrode 20 and the drain electrode 21 are connected to a part of the exposed source region 16s and a part of drain region 16d, respectively, via the contact holes. Thus, the TFT 7 is formed.

The source wiring line S (see FIG. 2) may include the same material as that for the source electrode 20 and the drain electrode 21 and in the same step as that for the source electrode 20 and the drain electrode 21, or include a material different from that for the source electrode 20 and the drain electrode 21 and in a step different from that for the source electrode 20 and the drain electrode 21.

Next, a photosensitive resin such as an acrylic or a polyimide is patterned on the second interlayer film 22 by applying, photolithography, and the like, to cover the TFT 7. Thus, the interlayer insulating film 23 is formed. Thus, the TFT substrate 40 is completed.

The gate electrode 18 of the TFT 7 formed in the TFT substrate 40 has the first metal film 18a that includes a metal material having the highest metal purity (purity of molybdenum or molybdenum alloy) of the gate electrode 18, the second metal film 18b that is layered on the first metal film 18a and includes a metal material obtained by oxidation or nitridation of the metal material, and the third metal film 18c that covers the first metal film 18a and the second metal film 18b and includes the metal material obtained by oxidation or nitridation of the metal material.

According to the configuration described above, the generation of needle-shaped and granular crystals on the surface of the gate electrode 18 can be certainly prevented. This can prevent the occurrence of problems such as deterioration of coverage for the gate electrode 18 and an increase in resistance value.

The thickness (t1) of the second metal film 18b is larger than the thickness (t2) of the third metal film 18c. According to the configuration described above, the generation of needle-shaped and granular crystals on the surface of the gate electrode 18 (a contact surface with the first interlayer film 19) can be certainly prevented.

### Method for Manufacturing Organic EL Display Device

After the TFT substrate 40 is completed, a contact hole is formed in a part of the interlayer insulating film 23 to expose the drain electrode 21, as illustrated in FIG. 1. At each of the pixels PIXs, the lower electrode 24 is formed in an island shape as a reflective electrode.

A resist material forming the edge cover 25 is applied to the entire surface of the substrate, to form a resist film. The resist film is patterned by photolithography. As a result, the edge cover 25 is formed in a lattice pattern to cover the edge of the lower electrode 24 arranged in a matrix (edge cover forming step). Further, the frame bank 35 is also formed to surround the display region 5 in a frame shape.

Subsequently, the organic EL layer 26 is patterned at the region surround by the edge cover 25 by vapor deposition by color or the like. The upper electrode 27 is formed on the organic EL layer 26 at the entire surface of the display region 5 by deposition or the like.

Subsequently, the sealing layer 42 is formed. Specifically, the inorganic layer 28 including silicon nitride or silicon oxide is formed to cover the upper electrode 27, the edge cover 25, and the interlayer insulating film 23 by CVD or the like. The organic layer 29 is formed on the inorganic layer 28 at the entire surface of the display region 5 by an inkjet method or the like. The inorganic layer 30 including silicon nitride or silicon oxide is formed on the organic layer 29 and the inorganic layer 28 by CVD or the like. As a result, the sealing layer 42 is formed.

After then, a drive circuit and the like are connected, to complete the organic EL display device 1. Note that, after the sealing layer 42 is formed, the support 11 may be changed from a glass substrate to a film, to make the organic EL display device 1 flexible.

In this embodiment, a case where the TFT substrate 40 is used in the organic EL display device 1 is described. However, a display device is not limited to the organic EL display device 1, and another display device such as a liquid crystal display device may be formed by using the TFT substrate 40.

### Experimental Results Regarding Needle-Shaped and Granular Crystals

Experimental results regarding needle-shaped and granular crystals will be described by using FIGS. 5A to 7B. A quantitative analysis was carried out by changing the annealing condition.

FIGS. 5A and 5B are views illustrating a state of the gate electrode that was removed from a furnace immediately after annealing the substrate having the gate electrode, thus abruptly bringing back the temperature to the atmospheric temperature (quenching). FIG. 5A illustrates a cross section of the gate electrode when the substrate having the gate electrode was removed from the furnace immediately after annealing. FIG. 5B is a result of quantitative analysis of the gate electrode of FIG. 5A.

FIGS. 6A and 6B are views illustrating a state of the gate electrode removed from a furnace, after the substrate having the gate electrode was annealed and allowing the temperature in the furnace to decrease down to 50° C. FIG. 6A illustrates a cross section of the gate electrode when the substrate having the gate electrode was annealed, then the temperature in the furnace was allowed to decrease down to 50° C., and then the substrate was removed from the furnace. FIG. 6B is a result of quantitative analysis of the gate electrode of FIG. 6A.

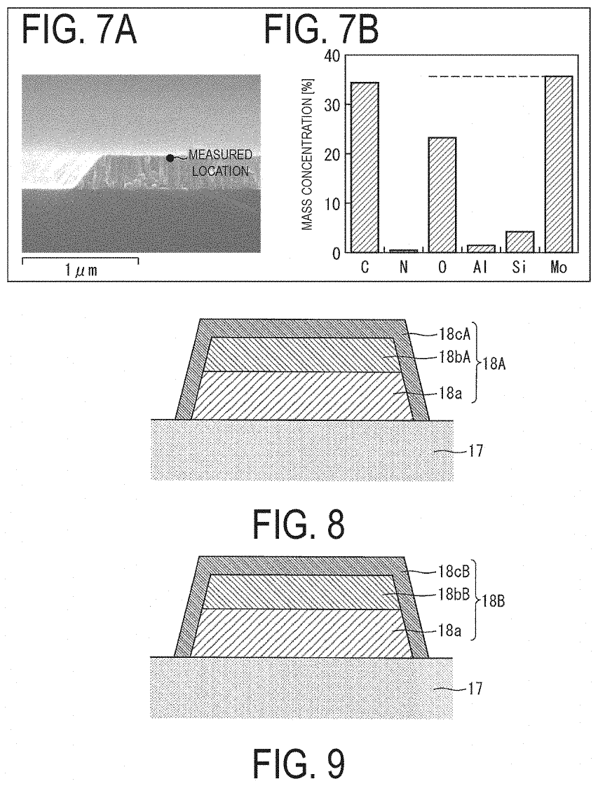

FIGS. 7A and 7B are views illustrating a state of the gate electrode removed from a furnace after annealing a substrate having the gate electrode in a low-oxygen environment.

FIG. 7A illustrates a cross section of the gate electrode when the substrate having the gate electrode was annealed in a low-oxygen environment and then removed from the furnace. FIG. 7B is a result of quantitative analysis of the gate electrode of FIG. 7A.

For the gate electrodes shown in FIGS. 5A to 7B, pure molybdenum was used. In annealing, the gate electrode was heated at 450° C.

When the gate electrode was quenched by removing the substrate from the furnace immediately after annealing, a needle-shaped crystal was formed on the surface of the gate electrode as shown in FIG. 5A. At a location named “measured location” illustrated in FIG. 5A, a quantitative analysis of elements was carried out. As seen from FIG. 5B, a large amount of carbon was detected, and molybdenum on the surface of the gate electrode was found to be oxidized.

After annealing, the temperature in the furnace was allowed to decrease down to 50° C., and the substrate was removed from the furnace. In such a case, a granular crystal was formed on the surface of the gate electrode as illustrated in FIG. 6A. At a location named “measured location” illustrated in FIG. 6A, a quantitative analysis of elements was carried out. As seen from FIG. 6B, a large amount of carbon was detected and molybdenum on the surface of the gate electrode was found to be oxidized.

The substrate was annealed in the furnace under reduced pressure in a low-oxygen environment and removed from the furnace. In such a case, neither needle-shaped nor granular crystals was formed on the surface of the gate electrode as illustrated in FIG. 7A. At a location named “measured location” illustrated in FIG. 7A, a quantitative analysis of elements was carried out. As seen from FIG. 7B, the carbon amount was substantially the same as the molybdenum amount and oxidation on the surface of the gate electrode was prevented.

On the cross section of the gate electrode that was not annealed, neither needle-shaped nor granular crystals was formed like FIG. 7A. In the gate electrode that was not annealed, the carbon amount was substantially the same as the molybdenum amount and the surface of the gate electrode was not oxidized in the same way as the result of quantitative analysis illustrated in FIG. 7B.

This shows that the needle-shaped and granular crystals formed on the surface of the gate electrode are formed by quenching molybdenum, which is oxidized by heat.

### Second Embodiment

A second embodiment of the disclosure will be described below. For easy description, components having the same functions as those of the components described in the first embodiment are appended with the same reference signs, and the description thereof is omitted.

FIG. 8 is a view illustrating a cross section of a gate electrode of a TFT substrate according to the second embodiment of the disclosure. The gate electrode 18 of the TFT 7 formed on the TFT substrate 40 may be a gate electrode 18A of FIG. 8.

The gate electrode 18A has the first metal film 18a including molybdenum or a molybdenum alloy, a second metal film 18bA that includes molybdenum nitride or molybdenum alloy nitride and layered on the first metal film 18a, and a third metal film 18cA that includes molybdenum oxide or molybdenum alloy oxide and covers the side surface of the first metal film 18a and the side surface and top surface of the second metal film 18bA.

After initiation of a plasma treatment during formation of the first metal film 18a, a predetermined time passes, and a nitrogen gas is then introduced into the furnace in the second step to form a film on the first metal film 18a. Patterning is carried out by etching in the gate electrode patterning step. Thus, the second metal film 18bA can be formed.

In the plasma treatment step (third step), a plasma treatment using oxygen is carried out. Thus, the third metal film 18cA can be formed.

According to the configuration of the gate electrode 18A, the first metal film 18a is covered with the second metal film 18bA and the third metal film 18cA. Therefore, the formation of needle-shaped and granular crystals on the surface of the gate electrode 18A can be prevented even when impurity ions are injected into the semiconductor layer 16, and the gate electrode 18A is heated for annealing of the semiconductor layer 16 with the gate electrode 18A exposed, followed by quenching. In addition, a reduction in production efficiency can be suppressed.

### Third Embodiment

A third embodiment of the disclosure will be described below. For easy description, components having the same functions as those of the components described in the first and second embodiments are appended with the same reference signs, and the description thereof is omitted.

FIG. 9 is a view illustrating a cross section of a gate electrode of a TFT substrate according to the third embodiment of the disclosure. The gate electrode 18 of the TFT 7 formed on the TFT substrate 40 may be a gate electrode 18B of FIG. 9.

The gate electrode 18B has the first metal film 18a including molybdenum or a molybdenum alloy, a second metal film 18bB that includes molybdenum oxide or molybdenum alloy oxide and layered on the first metal film 18a, and a third metal film 18cB that includes molybdenum oxide or molybdenum alloy oxide and covers the side surface of the first metal film 18a and the side surface and top surface of the second metal film 18bB.

After initiation of a plasma treatment during formation of the first metal film 18a, a predetermined time passes, and an oxygen gas is then introduced into the furnace in the second step to form a film on the first metal film 18a. Patterning is carried out by etching in the gate electrode patterning step. Thus, the second metal film 18bB can be formed.

In the plasma treatment step (third step), a plasma treatment using oxygen is carried out. Thus, the third metal film 18cB can be formed.

According to the configuration of the gate electrode 18B, the first metal film 18a is covered with the second metal film 18bB and the third metal film 18cB. Therefore, the formation of needle-shaped and granular crystals on the surface of the gate electrode 18B can be prevented even when impurity ions are injected into the semiconductor layer 16, and the gate electrode 18B is heated for annealing of the semiconductor layer 16 with the gate electrode 18B exposed, followed by quenching. In addition, a reduction in production efficiency can be suppressed.

### Fourth Embodiment

A fourth embodiment of the disclosure will be described below. For easy description, components having the same functions as those of the components described in the first to third embodiments are appended with the same reference signs, and the description thereof is omitted.

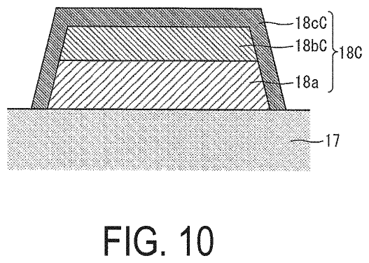

FIG. 10 is a view illustrating a cross section of a gate electrode of a TFT substrate according to the fourth embodiment of the disclosure. The gate electrode 18 of the TFT 7 formed on the TFT substrate 40 may be a gate electrode 18C of FIG. 10.

The gate electrode 18C has the first metal film 18a including molybdenum or a molybdenum alloy, a second metal film 18bC that includes molybdenum nitride or molybdenum alloy nitride and layered on the first metal film 18a, and a third metal film 18cC that includes molybdenum nitride or molybdenum alloy nitride and covers the side surface of the first metal film 18a and the side surface and top surface of the second metal film 18bC.

After initiation of a plasma treatment during formation of the first metal film 18a, a predetermined time passes, and a nitrogen gas is then introduced into the furnace in the second step to form a film on the first metal film 18a. Patterning is carried out by etching in the gate electrode patterning step. Thus, the second metal film 18bC can be formed.

In the plasma treatment step (third step), a plasma treatment using nitrogen or N₂O is carried out. Thus, the third metal film 18cC can be formed.

According to the configuration of the gate electrode 18C, the first metal film 18a is covered with the second metal film 18bC and the third metal film 18cC. Therefore, the formation of needle-shaped and granular crystals on the surface of the gate electrode 18C can be prevented even when impurity ions are injected into the semiconductor layer 16, and the gate electrode 18C is heated for annealing of the semiconductor layer 16 with the gate electrode 18C exposed, followed by quenching. In addition, a reduction in production efficiency can be suppressed.

### Fifth Embodiment

A fifth embodiment of the disclosure will be described below. For easy description, components having the same functions as those of the components described in the first to fourth embodiments are appended with the same reference signs, and the description thereof is omitted.

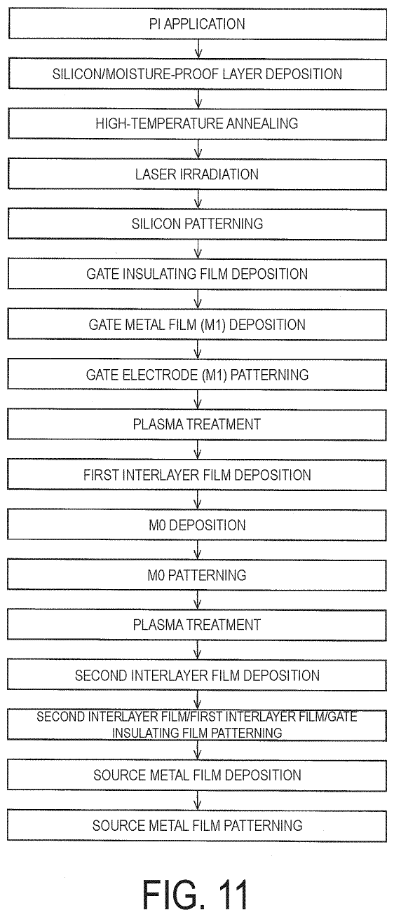

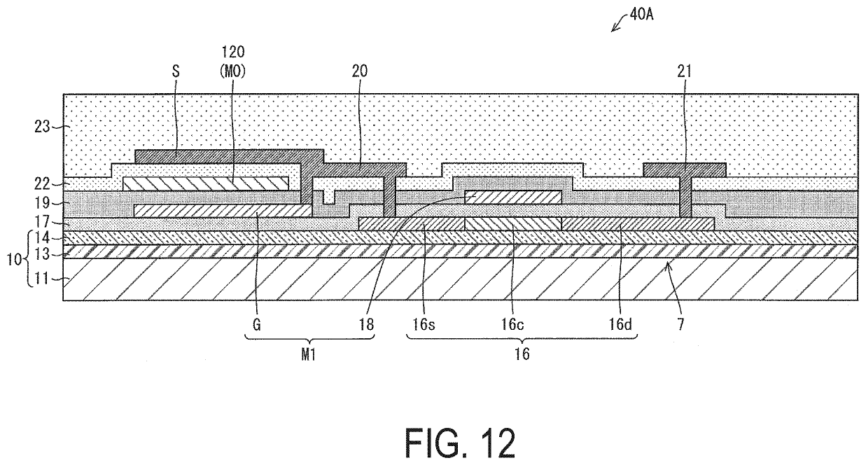

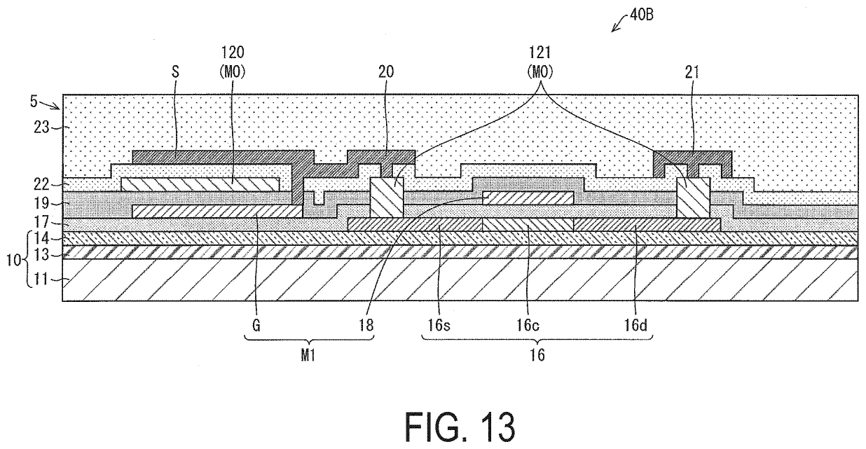

FIG. 11 is a chart showing a process of manufacturing a TFT substrate 40A according to the fifth embodiment of the disclosure. FIG. 12 is a cross-sectional view illustrating a configuration of the TFT substrate 40A according to the fifth embodiment of the disclosure. The organic EL display device 1 illustrated in FIG. 1 may have the TFT substrate 40A instead of the TFT substrate 40.

The TFT substrate 40A is manufactured in the same manner as in a method for manufacturing the TFT substrate 40 up to the interlayer film forming step (step (vi)) of forming the first interlayer film 19. In a method for manufacturing the TFT substrate 40A, the gate wiring line G is formed on the gate insulating film 17, wherein the gate wiring line G includes the same material as that for the gate electrode 18 and is formed in the same step as that for the gate electrode 18. Specifically, the gate wiring line G is formed by patterning from the first metal film 18a, the second metal film 18b, and the third metal film 18c.

Note that a metal layer of the layer, in which the gate electrode 18 and the gate wiring line G are formed, may be referred to as M1 layer.

After the first interlayer film 19 is formed in the interlayer film forming step (step (vi)), a capacitive wiring line 120 is formed by patterning on the first interlayer film 19 to be interposed between the gate wiring line G and the source wiring line S (capacitive wiring line forming step, step (vii)). Note that a metal layer of the layer, in which the capacitive wiring line 120 is formed, may be referred to as M0 layer.

The capacitive wiring line 120 includes the same material as those for the gate electrode 18 and the gate wiring line G in the same configuration as those for the gate electrode 18 and the gate wiring line G.

That is, in the capacitive wiring line forming step (step (vii)), a first capacitive wiring line metal film and a second capacitive wiring line metal film that form the capacitive wiring line 120 are formed on the entire surface of the first interlayer film 19 (capacitive wiring line forming step and capacitive wiring line metal film forming step). In this embodiment, the first and second capacitive wiring line metal films are formed by sputtering.

The metal material, that is a target, is placed in a furnace. In the furnace, the substrate 10 after completion of formation of the first interlayer film 19 is disposed to face the metal material. Herein, as the metal material, molybdenum or an alloy containing molybdenum is used.

Argon (Ar) as an inert gas is introduced into the closed furnace. A current is applied to an electrode to initiate sputtering. As a result, the first capacitive wiring line metal film is formed on the first interlayer film 19 (first capacitive wiring line forming step).

For example, the sputtering is carried out under conditions of from 0.2 to 0.5 Pa, from 3 to 10 W/cm², a flow rate of Ar of from 50 to 150 sccm, from 100 to 150° C., and from 100 to 300 nm.

After initiating the sputtering, an oxygen (O₂) gas or a nitrogen (N₂) gas is introduced into the furnace to form an oxide layer or a nitride layer in the upper layer of not less than 10 nm of the molybdenum or molybdenum alloy.

The control of film thickness during the sputtering is carried out depending on the number of magnet movement regardless of time.

For example, oxygen (O₂) or nitrogen (N₂) is introduced into the furnace during the last two to five magnet movements of all the magnet movements. A magnet is disposed on a back side of a target in the furnace, and has the same height as that of the target and a width of several tens centimeters. By the reciprocating motion of the magnet in the width direction, a metal film is deposited on the substrate.

Thus, the oxygen or nitrogen introduced into the furnace is added to molybdenum or a molybdenum alloy, to form the second capacitive wiring line metal film on the first capacitive wiring line metal film (second capacitive wiring line forming step).

Herein, oxygen is introduced into the furnace. As a result, molybdenum oxide or molybdenum alloy oxide as the second capacitive wiring line metal film is formed on the first capacitive wiring line metal film.

Therefore, the first and second capacitive wiring line metal films that form the capacitive wiring line 120 are formed on the entire surface of the first interlayer film 19.

Subsequently, the first and second capacitive wiring line metal films are patterned by dry etching or wet etching (capacitive wiring line patterning step).

Thus, the patterned first capacitive wiring line metal film and second capacitive wiring line metal film that form the capacitive wiring line 120 are formed.

Herein, the side surfaces of the first and second capacitive wiring line metal films are exposed. Because the second capacitive wiring line metal film includes oxidized molybdenum or oxidized molybdenum alloy, a needle-shaped or granular crystal is not likely to form on the surface even under heating followed by quenching. Because the first capacitive wiring line metal film includes molybdenum or a molybdenum alloy, a needle-shaped or granular crystal is likely to form on the exposed side surface under heating followed by quenching.

Subsequently, the first capacitive wiring line metal film having the exposed side surface and the second capacitive wiring line metal film are subjected to a plasma treatment using oxygen (O₂), nitrogen (N₂), or N₂O (plasma treatment step (second plasma treatment step), and third capacitive wiring line forming step).

The plasma treatment is carried out, for example, under conditions of from 0.2 to 1 W/cm², 50 to 300 Pa, a flow rate of N₂O of from 2000 to 5000 sccm, from 10 s to 60 s, and from 100 to 300° C.

Herein, the plasma treatment using nitrogen is carried out. Therefore, a third capacitive wiring line metal film that covers the side surface of the first capacitive wiring line metal film and the side surface and top surface of the second capacitive wiring line metal film is formed.

As a result, the capacitive wiring line 120 having the same configuration as those of the gate electrode 18 and the gate wiring line G is formed on the first interlayer film 19.

Subsequently, the second interlayer film 22 including silicon nitride or silicon oxide is formed on the capacitive wiring line 120 and the first interlayer film 19 by CVD or the like. Steps after this step are the same as those for the TFT substrate 40.

Thus, the capacitive wiring line 120 formed on the first interlayer film 19 has the first capacitive wiring line metal film including a metal material having the highest metal purity of the capacitive wiring line 120, the second capacitive wiring line metal film that includes a metal material obtained by oxidation or nitridation of the metal material and layered on the first capacitive wiring line metal film, and the third capacitive wiring line metal film that includes the metal material obtained by oxidation or nitridation of the metal material and covers the first and second capacitive wiring line metal films. Accordingly, the generation of needle-shaped and granular crystals on the surface of the capacitive wiring line 120 can be certainly prevented. This can prevent the occurrence of problems such as deterioration of coverage of the capacitive wiring line 120 and an increase in resistance value.

### Sixth Embodiment

A sixth embodiment of the disclosure will be described below. For easy description, components having the same functions as those of the components described in the first to fifth embodiments are appended with the same reference signs, and the description thereof is omitted.

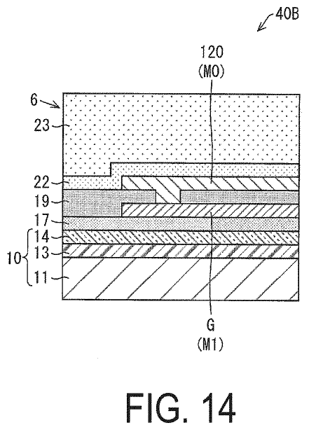

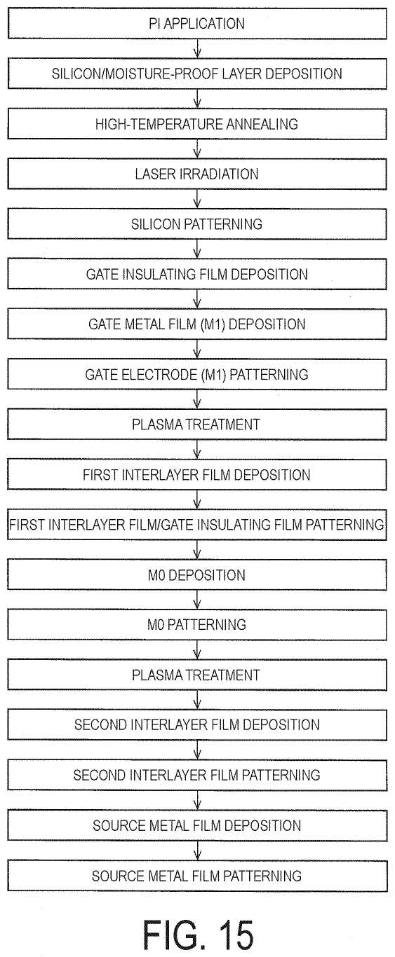

FIG. 13 is a cross-sectional view illustrating a configuration of a display region 5 of a TFT substrate 40B according to the sixth embodiment of the disclosure. FIG. 14 is a cross-sectional view illustrating a configuration of a frame region 6 of the TFT substrate 40B according to the sixth embodiment of the disclosure.

The organic EL display device 1 illustrated in FIG. 1 may have the TFT substrate 40B instead of the TFT substrate 40.

In a step of manufacturing the TFT substrate 40B, the first interlayer film 19 is formed during the insulating film forming step, and contact holes are formed by patterning the first interlayer film 19 and the gate insulating film 17 at the display region 5 while a part of the source region 16s and a part of the drain region 16d of the semiconductor layer 16 is exposed. At the frame region 6, a contact hole is formed to expose a part of the gate wiring line G (M1 layer).

In the capacitive wiring line forming step, the capacitive wiring line 120 (M0 layer) is formed on the first interlayer film 19. Thus, in the display region 5, a connection portion 121 (M0 layer) including the same material as that for the capacitive wiring line 120 in the same configuration as that for the capacitive wiring line 120 is formed in the contact hole of the first interlayer film 19. As a result, the connection portion 121 (M0 layer) is connected to each of the source region 16s and the drain region 16d of the semiconductor layer 16. At the frame region 6, a part of the capacitive wiring line 120 (M0 layer) is connected to the gate wiring line G (M1 layer) through the contact hole formed in the first interlayer film 19. Therefore, the capacitive wiring line 120 (M0 layer) is electrically connected to the gate wiring line G (M1 layer) at the frame region 6. Accordingly, the electrostatic destruction of the gate wiring line G and the capacitive wiring line 120 can be prevented at an early stage in the manufacturing process.

Subsequently, the TFT substrate 40B is completed like the TFT substrates 40 and 40A.

The organic EL display device 1 is manufactured by using the TFT substrate 40B. In this embodiment, when the sealing layer 42 is formed and each display region 5 formed in the substrate is cut and divided into individual pieces, a part where the capacitive wiring line 120 (M0 layer) is electrically connected to the gate wiring line G (M1 layer) at the frame region 6 is cut from the display region 5.

### Supplement

A method for manufacturing an active matrix substrate (TFT substrate 40) according to a first aspect of the disclosure is a method for manufacturing an active matrix substrate (TFT substrate 40) having the TFT 7 with a top gate structure on a substrate including: (i) forming the gate insulating film 17 on the substrate 10, the gate insulating film covering the semiconductor layer 16 formed in an island shape on the substrate; and (ii) forming the gate electrode G of the TFT 7 on the gate insulating film 17; wherein step (ii) includes (ii-a) a first step of forming the first metal film including the metal material forming the gate electrode in an inert gas atmosphere, (ii-b) a second step of adding oxygen or nitrogen to the inert gas atmosphere to form the second metal film 18b from the metal material on the first metal film 18a, and (ii-c) a third step of patterning the first metal film 18a and the second metal film 18b and subjecting the first metal film 18a and the second metal film 18b to a plasma treatment using oxygen or nitrogen.

According to the configuration, the second metal film can be formed on the first metal film by oxidation or nitridation of the metal material. The first and second metal films are patterned to expose the side surface of the first metal film including the metal material.

Then, the exposed side surface of the first metal film and the side surface and top surface of the second metal film are further oxidized or nitrided.

Thus, the third metal film that is oxidized or nitrided and covers the side surface of the first and second metal films is formed. The first metal film including the metal material is covered with the second and third metal films that are oxidized or nitrided, as described above. Therefore, even when the substrate is later heated for activation of the semiconductor layer, the formation of a needle-shaped or granular crystal on the surface of the gate electrode by heat can be prevented.

Further, even when the heated substrate is quenched for activation of the semiconductor layer, a needle-shaped or granular crystal is not likely to form on the surface of the gate electrode. Therefore, a reduction in productivity can be suppressed.

On the surface of the first metal film, the second metal film is layered. The second metal film includes the metal material by adding the oxygen or nitrogen. Therefore, the second metal film has a thickness larger than that of the third metal film formed by a plasma treatment using oxygen or nitrogen. Accordingly, the generation of needle-shaped and granular crystals on the surface of the first metal film can be certainly prevented.

According to the configuration, the generation of needle-shaped and granular crystals on the surface of the gate electrode can be certainly prevented. This can prevent the occurrence of problems such as deterioration of coverage of the gate electrode and an increase in resistance value.

A method for manufacturing an active matrix substrate (TFT substrate 40) according to a second aspect of the disclosure may include, after the third step in the first aspect, injecting impurity ions into the semiconductor layer 16 by using the gate electrode 18 as a mask, and annealing the semiconductor layer 16 after injecting impurity ions into the semiconductor layer 16.

According to the configuration, the semiconductor layer is annealed, resulting in activation. In the gate electrode, the first metal film including the metal material is covered with the second and third metal films. Therefore, even when heat is applied due to the annealing, the generation of needle-shaped and granular crystals on the surface can be prevented.

In a method for manufacturing an active matrix substrate (TFT substrate 40) according to a third aspect of the disclosure, the patterning the first and second metal films in the first and second aspects may be carried out by dry etching.

According to the configuration, a gate electrode having a tapered shape can be formed. Thus, the coverage of the gate electrode and the first interlayer film covering the gate electrode can be improved.

In a method for manufacturing an active matrix substrate (TFT substrate 40) according to a fourth aspect, the first metal film 18a in the first to third aspects may include molybdenum or a molybdenum alloy and the second metal film 18b in the first to third aspects may include molybdenum oxide, molybdenum nitride, a molybdenum oxide alloy, or a molybdenum nitride alloy. Thus, a gate electrode having a small resistance value can be formed.

A method for manufacturing an active matrix substrate (TFT substrate 40A) according to a fifth aspect includes: forming the gate wiring line on the gate insulating film, the gate wiring line being connected to the gate electrode; forming the interlayer film on the gate insulating film, the interlayer film covering the gate electrode and the gate wiring line; and forming the capacitive wiring line on the interlayer film, the capacitive wiring line overlapping with the gate wiring line via the interlayer film; wherein the capacitive wiring line forming step includes forming a first capacitive wiring line metal film in an inert gas atmosphere, adding oxygen or nitrogen to the inert gas atmosphere to form a second capacitive wiring line metal film on the first capacitive wiring line metal film, and patterning the first and second capacitive wiring line metal films and subjecting the first and second capacitive wiring line metal films to a plasma treatment using oxygen or nitrogen.

In a method for manufacturing an active matrix substrate (TFT substrate 40) according to a sixth aspect of the disclosure, the semiconductor layer 16 in the first to fifth aspects may include a low-temperature polysilicon.

A method for manufacturing an organic EL display device according to a seventh aspect of the disclosure may include forming the organic EL layer 26 and the sealing layer 42 sealing the organic EL layer 26 on the active matrix substrate (TFT substrate 40) manufactured by the method for manufacturing an active matrix substrate (TFT substrate 40) according to the first to sixth aspects.

In a method for manufacturing the organic EL display device 1 according to an eighth aspect of the disclosure including forming the organic EL layer 26 and the sealing layer 42 sealing the organic EL layer 26 on the active matrix substrate 40B manufactured by a method for manufacturing the active matrix substrate 40B, the capacitive wiring line forming step includes electrically connecting the gate wiring line G to the capacitive wiring line 120 via a contact hole formed in the interlayer film (first interlayer film 19) in the frame region 6 provided around the display region 5 including pixels arranged in a matrix and dividing the display region 6 into pieces, and the dividing includes dividing a part including the gate wiring line G and the capacitive wiring line 120 electrically connected via the contact hole in the frame region 6 and the display region 5. According to the configuration, the electrostatic destruction of the gate wiring line and the capacitive wiring line can be prevented at a relatively early stage in the manufacturing process.

An active matrix substrate (TFT substrate 40) according to a ninth aspect of the disclosure is an active matrix substrate (TFT substrate 40) having the TFT 7 with a top gate structure including: the gate insulating film 17 formed on the substrate 10, the gate insulating film covering a semiconductor layer 16 formed in an island shape on the substrate; and the gate electrode 18 of the TFT 7 formed on the gate insulating film 17, wherein the gate electrode 18 includes the first metal film 18a including a metal material having the highest metal purity among the gate electrode, the second metal film that includes a metal material obtained by oxidation or nitridation of the metal material and layered on the first metal film, and the third metal film that includes the metal material obtained by oxidation or nitridation of the metal material and covering the first and second metal films.

According to the configuration, the generation of needle-shaped and granular crystals on the surface of the gate electrode can be certainly prevented. This can prevent the occurrence of problems such as deterioration of coverage of the gate electrode and an increase in resistance value.

In an active matrix substrate (TFT substrate 40) according to a tenth aspect of the disclosure, the second metal film may have a thickness greater than that of the third metal film. According to the configuration, the generation of needle-shaped and granular crystals on the surface of the gate electrode can be more certainly prevented.

The present invention is not limited to each of the embodiments stated above, and various modifications may be implemented within a range not departing from the scope of the claims. Embodiments obtained by appropriately combining technical approaches stated in each of the different embodiments also fall within the scope of the technology of the present invention. Moreover, novel technical features may be formed by combining the technical approaches stated in each of the embodiments.

### REFERENCE SIGNS LIST

1 Organic EL display device
2 Organic EL substrate
5 Display region
6 Frame region
7 TFT
10 Substrate
16 Semiconductor layer
16c Channel region
16s Source region
16d Drain region
17 Gate insulating film
18 Gate electrode
18a, 18aA to 18aC First metal film
18b, 18bA to 18bC Second metal film
18c, 18cA to 18cC Third metal film
19 First interlayer film (interlayer film)
20 Source electrode
21 Drain electrode
22 Second interlayer film
23 Interlayer insulating film
24 Lower electrode
25 Edge cover
26 Organic EL layer
27 Upper electrode
28, 30 Inorganic layer
29 Organic layer
35 Frame bank
40, 40A, 40B TFT substrate (active matrix substrate)
41 Organic EL element
42 Sealing layer
120 Capacitive wiring line

1. A method for manufacturing an active matrix substrate including a Thin Film Transistor (TFT) with a top gate structure on a substrate, the method comprising:
(i) forming a gate insulating film on the substrate, the gate insulating film covering a semiconductor layer formed in an island shape on the substrate; and
(ii) forming a gate electrode of the TFT on the gate insulating film,
wherein step (ii) includes (ii-a) forming a first metal film in an inert gas atmosphere, (ii-b) adding oxygen or nitrogen to the inert gas atmosphere to form a second metal film on the first metal film, and (ii-c) patterning the first metal film and the second metal film and subjecting the first metal film and the second metal film to a plasma treatment using oxygen or nitrogen.

2. The method for manufacturing an active matrix substrate according to claim 1, further comprising:
(iii) implanting an impurity ion into the semiconductor layer by using the gate electrode as a mask after step (ii-c); and
(iv) annealing the semiconductor layer after step (iii).

3. The method for manufacturing an active matrix substrate according to claim 1,
wherein step (ii-c) is performed by dry etching.

4. The method for manufacturing an active matrix substrate according to claim 1,
wherein the first metal film includes molybdenum or a molybdenum alloy, and the second metal film includes molybdenum oxide, molybdenum nitride, a molybdenum oxide alloy, or a molybdenum nitride alloy.

5. The method for manufacturing an active matrix substrate according to claim 1 comprising:
(v) forming a gate wiring line on the gate insulating film, the gate wiring line being connected to the gate electrode;
(vi) forming an interlayer film on the gate insulating film, the interlayer film covering the gate electrode and the gate wiring line; and
(vii) forming a capacitive wiring line on the interlayer film, the capacitive wiring line overlapping the gate wiring line via the interlayer film,
wherein step (vii) includes (vii-a) forming a first capacitive wiring line metal film in an inert gas atmosphere, (vii-b) adding oxygen or nitrogen to the inert gas atmosphere to form a second capacitive wiring line metal film on the first capacitive wiring line metal film, and (vii-c) patterning the first capacitive wiring line metal film and the second capacitive wiring line metal film and subjecting the first capacitive wiring line metal film and the second capacitive wiring line metal film to a plasma treatment using oxygen or nitrogen.

6. The method for manufacturing an active matrix substrate according to claim 1,
wherein the semiconductor layer includes a low-temperature polysilicon.

7. A method for manufacturing an organic EL display device comprising:
forming an organic EL layer and a sealing layer sealing the organic EL display device on an active matrix substrate manufactured by the method for manufacturing an active matrix substrate according to claim 1.

8. A method for manufacturing an organic EL display device comprising:
forming an organic EL layer and a sealing layer sealing the organic EL layer on the active matrix substrate manufactured by the method for manufacturing an active matrix substrate according to claim 5,
wherein step (vii) includes (vii-d) electrically connecting the gate wiring line to the capacitive wiring line through a contact hole formed in the interlayer film in the frame region provided around the display region including pixels arranged in a matrix, and (vii-e) partitioning the display region into individual partitions, and
step (vii-e) includes partitioning the display region from a part including the electrical connection between the gate wiring line and the capacitive wiring line via the contact hole in the frame region.

9. An active matrix substrate including a TFT with a top gate structure on a substrate comprising:
a gate insulating film formed on the substrate, the gate insulating film covering a semiconductor layer formed in an island shape on the substrate; and
a gate electrode of the TFT formed on the gate insulating film,
wherein the gate electrode includes a first metal film including a metal material having the highest metal purity of the gate electrode, a second metal film layered on the first metal film, the second metal film including a metal material obtained by oxidation or nitridation of the metal material, and a third metal film covering the first and second metal films, the third metal film including the metal material obtained by oxidation or nitridation of the metal material, and
the second metal film has a thickness greater than the thickness of the third metal film.

10. (canceled)
